(19) United States
(12) Patent Application Publication
(10) Pub. No.: US 2013/0335822 A1
(43) Pub. Date: Dec. 19, 2013

(54) METHOD FOR MANUFACTURING TOUCH-SENSITIVE ELEMENT ON POLARIZER AND POLARIZATION DEVICE

(71) Applicants: YU-CHOU YEH, TAOYUAN COUNTY (TW); JUI-MING NI, TAOYUAN COUNTY (TW); PING-HSU LAI, TAOYUAN COUNTY (TW); HSIAO-SHUN JAN, TAOYUAN COUNTY (TW); CHENG-HSIUNG WU, TAOYUAN COUNTY (TW)

(72) Inventors: YU-CHOU YEH, TAOYUAN COUNTY (TW); JUI-MING NI, TAOYUAN COUNTY (TW); PING-HSU LAI, TAOYUAN COUNTY (TW); HSIAO-SHUN JAN, TAOYUAN COUNTY (TW); CHENG-HSIUNG WU, TAOYUAN COUNTY (TW)

(73) Assignee: J TOUCH CORPORATION, TAOYUAN COUNTY (TW)

(21) Appl. No.: 13/525,453

(22) Filed: Jun. 18, 2012

(51) Int. Cl. G02B 5/30; B05D 3/06; B05D 1/18; C23C 16/455; C23C 14/34; B05D 1/02; B05D 5/06; B44C 1/22

(52) U.S. Cl. 359/483.01; 427/97.4; 427/558; 216/13; 427/96.8

(57) ABSTRACT

The disclosure is related to a method for manufacturing touch-sensitive element on a polarizer, and a polarization device made by the method. In one of the embodiments of the invention, a polarizing substrate is firstly prepared. The method then coats first transparent conductive material onto the substrate, and uses a patterning process to form multiple sensing areas and wiring areas. There are continuous paths and adjacent non-continuous paths are existed in between the sensing areas. A bridged insulating layer is formed as processing the step for spray-coating or inject-printing insulating material upon the areas of the non-continuous pads. A bridged conductive layer is formed upon the insulation layer as spray-coating or inject-printing a second transparent conductive material there-on. The bridged conductive layer is to electrically connect the non-continuous pads. The method is therefore forming the polarization device with the touch-screen elements.

### BACKGROUND

1. Technical Field

The disclosure is related to a method for manufacturing touch-sensitive element onto a polarizer and a produced polarization device, in particular, a thinning procedure is introduced to producing a touch-sensitive element onto a polarizer of display and also a related touch-controlled polarization device.

2. Description of Related Art

Such as an ordinary liquid-crystal display (LCD), a driver chip is configured to change voltage of the top and bottom electrode layers for generating an electric field applied to a liquid crystal layer therein. The electric field formed between the electrode layers is used to alter alignment and orientation of the liquid crystal molecules. The altering of the LC molecules is served to define the state of allowing the light from the source to pass through the device or not. In order to generate colors, a color filter is usually disposed within the LCD for altering the colors of pixels as the light passing through the filter.

The liquid crystal layer is sandwiched in between a top polarizer and a bottom polarizer in the LCD structure. The polarizer is functioned to turn the incident unpolarized light to a polarized light, by which the polarizer allows pass the light from a light source with a specific polarization, and block the waves with other polarizations. The LCD uses the features of polarization and the orientation of LC molecules to control its lighting state as allowing the light to be or not to be passed.

A schematic diagram shown in FIG. 1 describes a conventional touch-controlled display module. The display desired to have touch-controlled feature is usually combined with a touch-controlled module. A sensing circuit is also introduced to obtaining the position where the user contacts the touch-controlled display. The display module shown in the figure is implemented by constituting a touch-controlled module 101 and an LCD module.

A liquid crystal layer 105 of the shown display module is particularly sandwiched in between a top substrate 104 and a bottom substrate 106. Furthermore, a top polarizer 102 is attached with the top surface of the top substrate 104 by optical glue 103. A bottom polarizer 108 is adhered with the bottom substrate 106 by optical glue 107.

In the figure, a light source 111 is disposed below the display module. Its top surface is mounted with a touch-controlled module 101, and electrically connected to a driver chip 109 which is for controlling the voltage for the electrode layers of the LCD. The driver chip 109 is electrically connected with a circuit substrate 110, by which the system is configured to drive the display. The bottom polarizer 108 of LCD (e.g. TFT LCD) is functioned to turn the unpolarized light from the light source 111 to a polarized light with unitary polarization. The angles of polarization of the bottom polarizer 108 and the top polarizer 102 are perpendicular. The polarization of the light may be changed due to the electric field as the light passing through the liquid crystal layer 105, and the top polarizer 102 is applied to defining the shading level.

For introducing the touch-controlled feature into the display module, an additional touch-controlled module 101 is conventionally provided to be mounted onto the surface of the panel. However, the thicker structure and high cost of those assemblies of the conventional touch-controlled display module are required to be improved.

The above description should not be deemed to limit the scope of this invention, which should be properly determined on the basis of the attached claims.

### SUMMARY

For solving the drawbacks caused by the mentioned display module in the conventional technology, a method for directly manufacturing touch-sensitive elements onto surface of a polarizer is provided. The present method is preferably to produce a miniaturized thin polarization device mounted with the touch-sensitive elements.

According to one of the embodiments of the present invention, the method for manufacturing the polarization device with the touch-sensitive element includes the steps of: firstly, a substrate with light polarization is prepared, such as the polarizer generally used in the liquid crystal display (LCD), and a first transparent conductive material is then coated onto the surface of the substrate. A patterning procedure is incorporated into the process for forming a plurality of areas including first electrodes, first electrode leads, second electrodes, second wires, and second electrode leads on the substrate, for example by an etching technology. The first electrodes and the second electrodes are respectively forming the electrical pads on the substrate along different axial directions, for example an X-axis and a Y axis. In which, the plurality of adjacent first electrodes are non-continuous pads, and the second electrode and another adjacent electrode are connected through a second wire. The first electrode leads are separately leaded to the first electrodes along the one axial direction. The second electrode leads are leaded to the continuous second electrodes along their specific axial direction.

The portion across the adjacent first electrodes forms a non-continuous path. An insulating material is then formed at the portion between the non-continuous first electrodes by spray-coating or inject-printing process. The material forms a bridged insulating layer there-between. After that, a second transparent conductive material is formed upon the bridged insulating layer, especially by spray-coating or inject-printing process. The second transparent conductive material and the bridged insulating layer are then processed by a curing process, such as a UV curing or a thermo curing. A first wire is therefore formed onto the bridged insulating layer for bridging the non-continuous first electrodes.

The above-described method is especially used to form the touch-controlled component onto the surface of the polarization device. This polarization device structurally includes a substrate with function of light polarization, a plurality of patterned first electrodes, first electrode leads, second electrodes, second wires and second electrode leads made by the first transparent conductive material. The device also includes the bridged insulating layers inject-printed with insulating material, and the first wires formed by inject-printing and curing the second transparent conductive materials.

It is noted that the described first transparent conductive material and the second transparent conductive material may be the same material, for example the conductive material with light transmittance higher than 85%. The coating process to form the first transparent conductive material onto the substrate may be implemented by a dry precision-coating process or a wet precision-coating process.

In order to further understand the techniques, means and effects of the present disclosure, the following detailed descriptions and appended drawings are hereby referred, such that, through which, the purposes, features and aspects of the present disclosure can be thoroughly and concretely appreciated; however, the appended drawings are merely provided for reference and illustration, without any intention to be used for limiting the present disclosure.

### BRIEF DESCRIPTION OF THE DRAWINGS

FIG. 1 describes a schematic diagram of a conventional touch-controlled display module;

FIG. 2 shows a flow chart illustrating the embodiment of manufacturing the polarizer with touch-sensitive element in accordance with the present invention;

FIGS. 3A, 3B, 3C, 3D, and 3E schematically describe an embodiment of manufacturing the polarizer with touch-sensitive element in accordance with the present invention;

FIGS. 4A, 4B, and 4C shows the embodiment of manufacturing bridging channel of the polarization device in accordance with the present invention;

FIG. 5 shows an embodiment of the assembly of the polarization device and a display module according to the present invention.

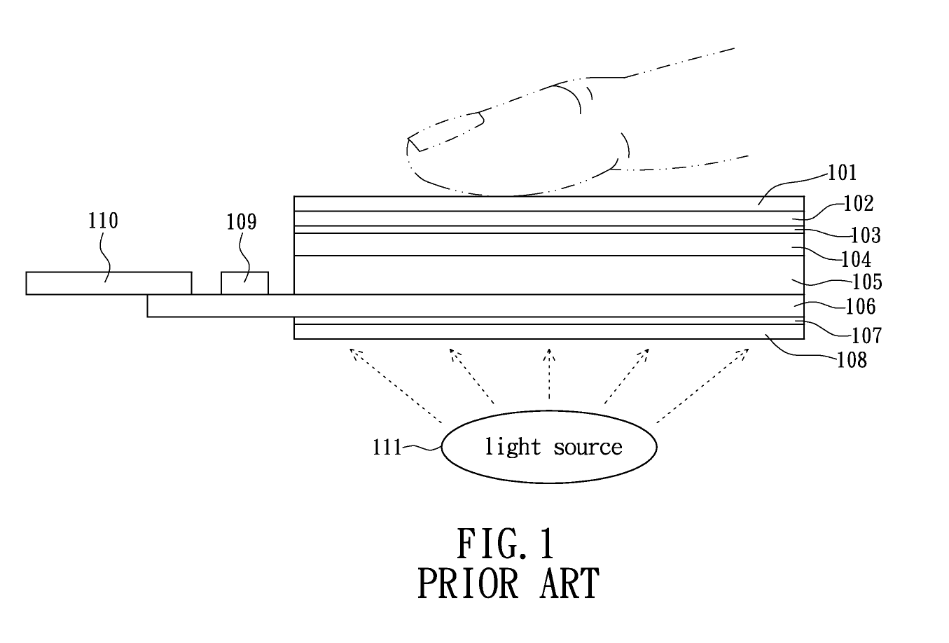

### DESCRIPTION OF THE EXEMPLARY EMBODIMENTS

Reference will now be made in detail to the exemplary embodiments of the present disclosure, examples of which are illustrated in the accompanying drawings. Wherever possible, the same reference numbers are used in the drawings and the description to refer to the same or like parts.

The disclosure related to the present invention is directed [symbol] to a method for manufacturing a polarization device having touch-sensitive elements. One of the embodiments of the present invention is to produce a polarizer which is generally used in a liquid crystal display, and a surface of the polarizer is formed with touch-sensitive elements made by the method. The method miniaturizes the display by the thinning procedure performed on producing the polarizer. A polarization device with function of touch control is then introduced. The touch-controlled polarization device with originally light polarization may be incorporated into a capacitance-type display. Therefore a touch-embedded display without additional touch-controlled panel is accomplished.

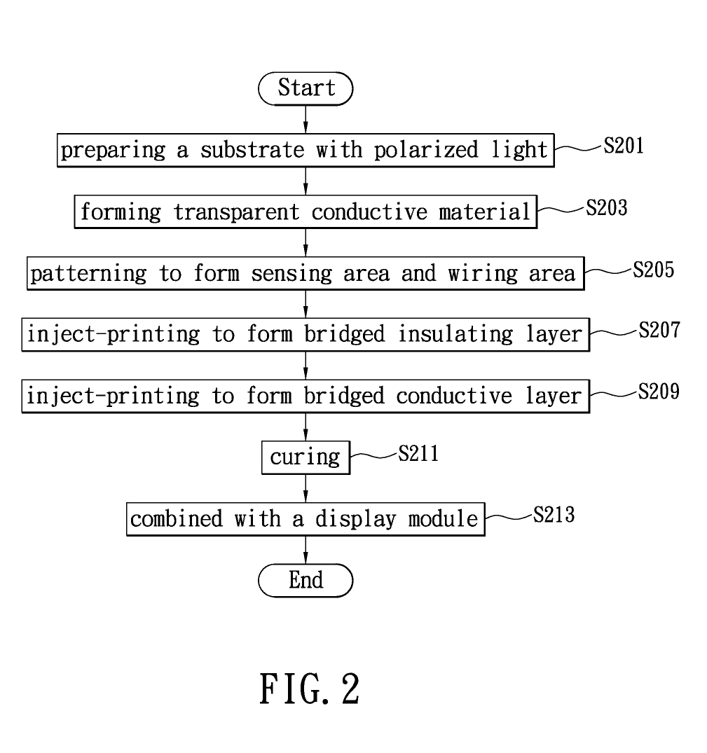

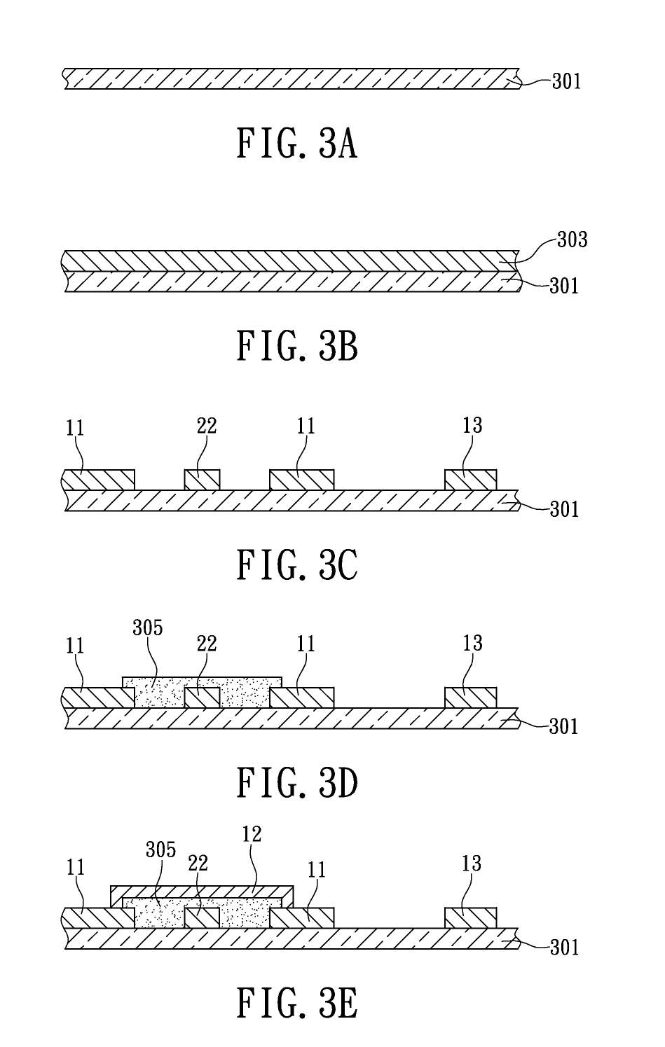

The flow chart shown in FIG. 2 illustrates the method for manufacturing the polarizer with touch-sensitive elements. The description of FIG. 2 may be also in view of the embodiments schematically shown in FIGS. 3A, 3B, 3C, 3D, and 3E.

The exemplary process includes a first step of preparing a substrate with light polarization, such as in step S201. The substrate with function of polarizing the light may be incorporated as a polarizer used in a display module, for example the polarizer 301 shown in FIG. 3A. The polarizer is particularly a high light transmittance polarizer, which is preferably with a light transmittance higher than 85%. The polarizer may be served as a polarizer within a flat display. In an exemplary example, surface of the polarizer is processed with a surface treatment to be with choking gas such as moisture and oxygen, and transparent harden treatment layer.

In step S203, a coating process may be used to form a first transparent conductive material upon surface of the substrate. For example, a dry-coating procedure or wet-coating procedure may be introduced. The conductive material 303 shown in FIG. 3B is thus formed. One of the embodiments of the substrate can be a polarizer in the display module. It is noted that, for the use of touch screen, the first transparent conductive material is preferred to be a high light-transmittance conductive material, exemplarily with the light transmittance higher than 85%.

In the present step, the coating method is preferably a technology of precision coating. In which, the conductive material with high light transmittance is uniformly coated onto the substrate with function of light polarization. The precision coating may be a dry process or a wet process. The film may be configured to have a thickness between 0.01 um and 10 um. The error thereof is exemplarily within 15%. The first transparent conductive material may be one selected from Indium tin oxide (ITO), nano silver, nano Cu, conductive polymer, Carbon nano tube, Graphene, AgBr, and Indium Gallium Zinc Oxide (IGZO). It is noting that the conductive polymer is a kind of chemical derivative with doping structure which includes, but not limited to, polyaniline, polythiophene and their derivatives.

While the mentioned dry process is used to form the first transparent conductive material, the major process may be sputtering, evaporation, or Chemical Vapor Deposition (CVD). Alternatively, the wet process may be used to implement the coating, such as slot-die process, gravure, dipping in chemical solution, inject-printing, or spray-coating process.

In accordance with one of the embodiments, rather than the double-layer sensors mounted on a traditional capacitance-type touch screen, an aspect of single-layer sensors is particularly introduced to the touch screen. It is noted that the double-layer sensors use two different sensing layers respectively forming X-directional and Y-directional sensing electrodes, and contrarily the single-layer layout includes the sensing electrodes along both X and Y directions. One of the objectives of the present invention is to provide a solution for forming the layout with two-directional electrodes on the single layer.

In step S205, a patterning method is used to form the first transparent conductive material upon the surface of substrate. A plurality of sensing areas and signal wiring areas are formed onto the substrate with the transparent conductive material. The sensing areas and the signal wiring areas are particularly forming the sensing electrodes and the wires for the touch screen.

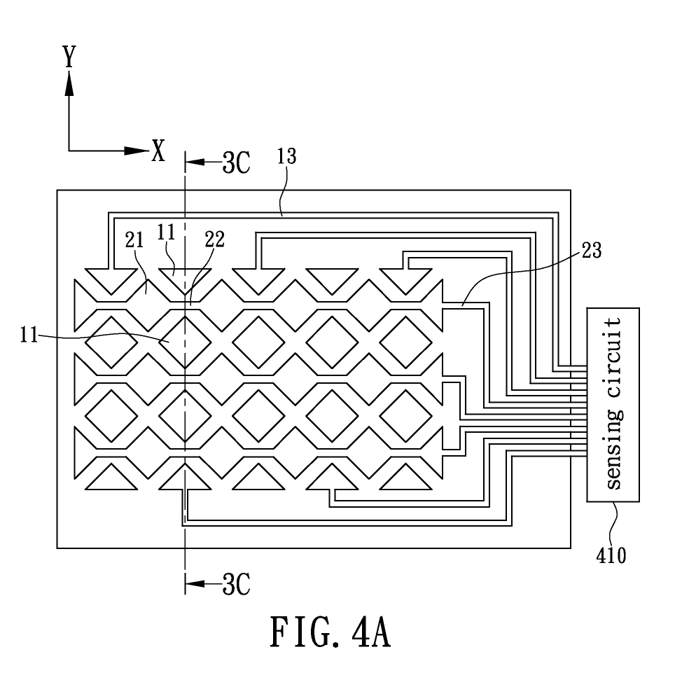

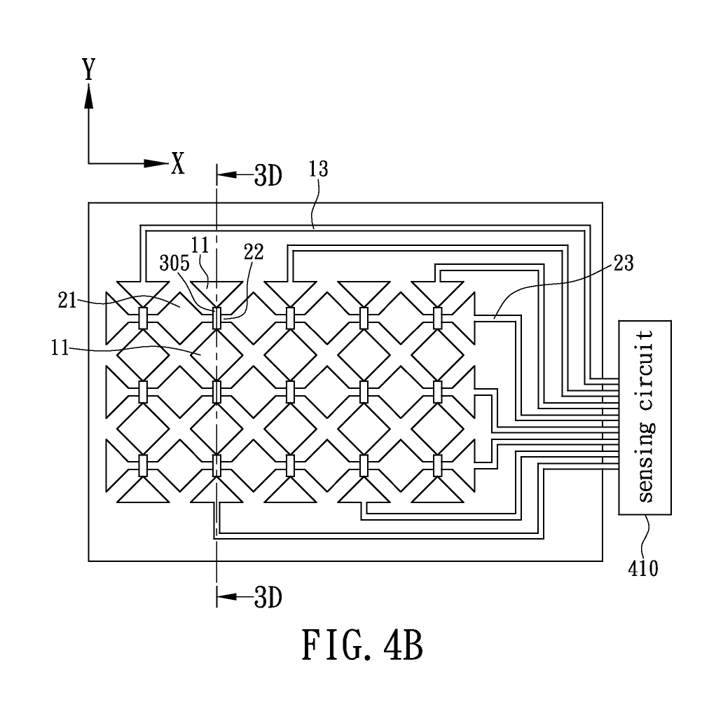

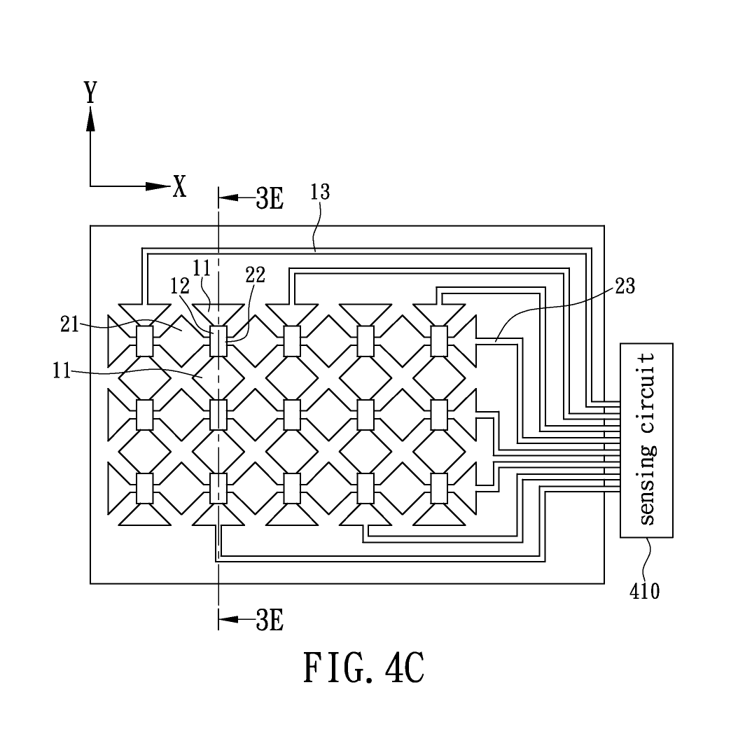

Reference is made to FIG. 4A, it is not limited to, the first electrodes (11) and the second electrodes (21) are respectively forming the X and Y-directional electrodes.

The sensing areas onto a single layer may respectively form a plurality of sensing areas with non-continuous paths and continuous paths between the adjacent areas along two different axes. In the exemplary example, the series of first electrodes (11) form the non-continuous paths, and the second electrodes (21) form the continuous paths as the shown second wires (22). The axial direction made by the first electrodes (11) forms the circuit with multiple paths. In precise, the shown first electrode leads (13) are leaded to external circuit. Further, the second electrodes (21) are leaded to the external circuit by the second electrode leads (23) formed along the other axial direction.

The mentioned patterning process may be implemented by an etching method generally applied to semiconductor manufacture. A dry-etching procedure or wet-etching procedure is one of the solutions embodying the etching process.

For example, the dry-etching procedure uses etching pastes to form the first transparent conductive material. Furthermore, laser engraving or shutter-mask evaporation is also the solution to perform the patterning process. The sensing areas and signal wiring areas are therefore formed upon the substrate surface.

Still further, the dry-etching procedure is specifically sorted as two extremely different methods which are a pure physical etching and a pure chemical reactive etching. In which, the pure physical etching process is regarded as a method of physical sputtering. The physical sputtering uses a method of glow discharge to dissociate gas into positively-charged ions, and accelerate the ions with a bias voltage. Therefore, the surface of the etching object is sputtered and the atoms of the object are driven out. The dry-etching process may also conduct a chemical reaction and an ion-assisted etching in order to form a protective layer from etching the side areas and removing residues.

The mentioned wet-etching process for forming the areas exemplarily by a photolithography method involved with light exposing, developing, and etching. In the wet-etching process, a photoresist is firstly used to cover the portion of the first transparent conductive material which needs not to be etched. For example, the areas desired to be the sensing areas and the signal wiring areas should be covered by the photoresist. A specific chemical solution is then applied to etch the uncovered portion. The remaining material can be removed in this etching process since it turns to the compound that is dissolved in the chemical solution. The wet-etching process is essentially to conduct the chemical reaction between the solution and the material to be etched. The solution is applicably obtained by mixing the selected compounds.

The essential steps of the wet-etching process include spreading the chemical solution over the surface of the conductive material, reacting the solution and the material to be etched, dispersing the reacted product to the solution from the surface, and the draining the remnant with the solution.

After patterning the surface conductive material, such as step S205, in view of FIG. 3C, the areas of first electrode 11, second wires 22 between the adjacent second electrodes (not shown), and first electrode wires 13 bridging the first electrodes are made by etching the conductive material 303. The sectional diagram shown in FIG. 3C is referred to the dotted line indicative of the profile line 3C in FIG. 4A.

The above-described plurality of first electrodes and the second electrodes are formed as the sensing electrodes evenly distributed over the same plane. A portion of the electrodes, such as the second electrodes, forms the interconnected electrodes creating the continuous paths along a specific axial direction. Therefore the signals made by the second electrodes represent the sensing signals of this axial direction. The other portion of the electrodes, such as the first electrodes, forms the non-continuous electrical paths along the other axial direction.

For making the bridges between the non-continuous sensing electrodes, such as the step S207, an inject-printing process is used to form bridged insulating layers over the non-continuous gaps. For example, an oxide layer may form the insulating layer by this inject-printing process. Reference is made to FIG. 3D, a bridged insulating layer 305 is formed upon the position between the two first electrodes 11, and the position is also across the second wire 22 between the second electrodes in the other axial direction. The sectional diagram shown in FIG. 3D is corresponding to the profile line 3D in FIG. 4B. The sectional view of the structure indicates a bridged insulating layer 305 formed between the two first electrodes 11.

Next, in step S209, a transparent conductive material is further inject-printed onto the bridged insulating layers. This transparent conductive material is such as the described second transparent conductive material. It is noting that the conductive material may be shaped by UV curing or thermo curing the material. The curing process is used to form the first wire 12 upon the bridged insulating layer 305 as shown in FIG. 3E and FIG. 4C. The diagram in FIG. 3E is drawn corresponding to the profile line 3E shown in FIG. 4C. The mentioned conductive material is such as the transparent conductive material applied to form the sensing areas the signal wiring areas, which are exemplarily used to be the first electrodes, second electrodes, and the related leads.

In practice, the conductive material may be the one selected from Indium tin oxide (ITO), nano silver, nano Cu, conductive polymer, carbon nano tube, Graphene, and AgBr, Indium Gallium Zinc Oxide (IGZO). The conductive polymer is preferably made by the chemical derivative of a specific doping structure, for example, but not limited to, the polyaniline and its derivative, or the polythiophene and its derivative.

According to one of the embodiments, the transparent conductive material, such as the mentioned first transparent conductive material, coated on the substrate is used to form the sensing areas and the signal wiring areas may be identical to the material forming the bridged conductive layer, such as the second transparent conductive material. Still, it is not limited that the first and the second transparent conductive materials are not the same material. It is also noted that the light transmittance of the second transparent conductive material may be higher than 80% since it incorporates the bridged conductive layers which occupy relatively smaller areas.

The inject-printing process described in steps S207 and S209, in accordance with one embodiment, is able to form the very precision lines such as to form the high light-transmittance insulating layers and the bridged conductive layers onto the non-continuous paths in between the first electrodes (11). Reference is made to FIG. 4A; the Y-directional non-continuous paths are inject-printed with the droplets ranged from 0.1 um to 5 um. In step S211, the UV curing or thermo curing process is configured to form the bridged conductive layers onto the non-continuous points across the continuous electrodes. The bridged conductive layers exemplarily form the first wires 12, such as the diagram shown in FIG. 3E, which bridge the adjacent first electrodes (11).

The substrate with function of light polarization is such as a polarizer used in an LCD module. The polarizer, and its surface-mounted first electrodes and second electrodes along the different axial directions, bridged insulating layers and first wires in between the first electrodes, second wires in between the second electrodes, and further the first electrode leads and second electrode leads leaded to a sensing circuit constitute the polarization device with surface touch-controlled components.

In step S213, the polarization device made by the above-discussed method is then combined with a display module. The display module therefore includes a polarizer with function of touch controlling.

The mentioned display module is such as an ordinary liquid crystal display (LCD) or an organic light-emitting diode (OLED) display. The LCD may be one of the types including TN, STN, TFT, and LTPS. The OLED may be a type using small molecule or polymer, and used to be an OLED display driven by active matrix or passive matrix.

According to the embodiment of the claimed method for manufacturing the polarizer with touch-sensitive elements, the discussed conductive polymer and the precision inject-printing process may embody a product with low-temperature electrode bridges, sensors with high accuracy and linearity, and narrow frames. In which, the environment is preferably with temperature ranged from 80-degree to 90-degree Celsius. It is worth to note that one of the objectives to conduct the method at a low temperature is because of the claimed polarizer of the invention may not endure to high temperature.

FIGS. 4A, 4B, 4C schematically show the embodiment with the steps of producing the bridging channels in the polarization device.

FIG. 4A shows a surface with a plurality of pads after a patterning process. The wires are simultaneously formed with the pads. It is apparent that the pads indicative of the discussed second electrodes (21) disposed form the continuous paths along X direction. On the other hand, the Y direction exists the plurality of pads, such as the discussed first electrodes (11), forming the non-continuous paths.

In the present example, the second electrodes 21 are serially connected via the second wires 22 in the X direction. One end of each direction with the connected second electrodes 212 is connected with a sensing circuit 40 via a second electrode lead 23. In the Y direction, for avoiding the electrical interference or short circuit, the first electrodes 11 form the non-continuous pads in the earlier stage when they are in the same plane with the second electrodes 21. Every first electrode lead 13 leaded to the sensing circuit 410 is connected with each path of the first electrodes 11.

The electrode leads along the two axial directions may be collectively linked to one side of the polarization device for conveniently connected to the sensing circuit 410. In the preferred embodiment, the leads may be formed with the shown pads simultaneously by the patterning process. The materials for forming both the leads and the pads are kind of transparent conductive materials. It is noted that the transparent conductive materials for the leads and the pads may be the same of different materials.

Reference is now made to FIG. 4B. The inject-printing process is incorporated to forming the insulating matters in between the non-continuous pads. The present example shows the first electrodes 11 along the Y direction forming the non-continuous paths. The shown bridged insulating layer 305 is formed in between the adjacent first electrodes 11 and is across the connected second electrodes 21 along the X direction. FIG. 2 and FIG. 3D describe the step for producing the bridged matter. FIG. 3D is drawn by corresponding to the profile line 3D.

FIG. 4C shows the first wire 12 is formed onto the bridged insulating layer (305) in between the first electrodes 11 by the inject-printing process. The relevant process is referred to the descriptions of FIG. 2 and FIG. 3E. The diagram in FIG. 3E is drawn in view of the profile line 3E. The first wire 12 is particularly electrically isolated with the second electrode 21 in the X direction by the bridged insulating layer 305.

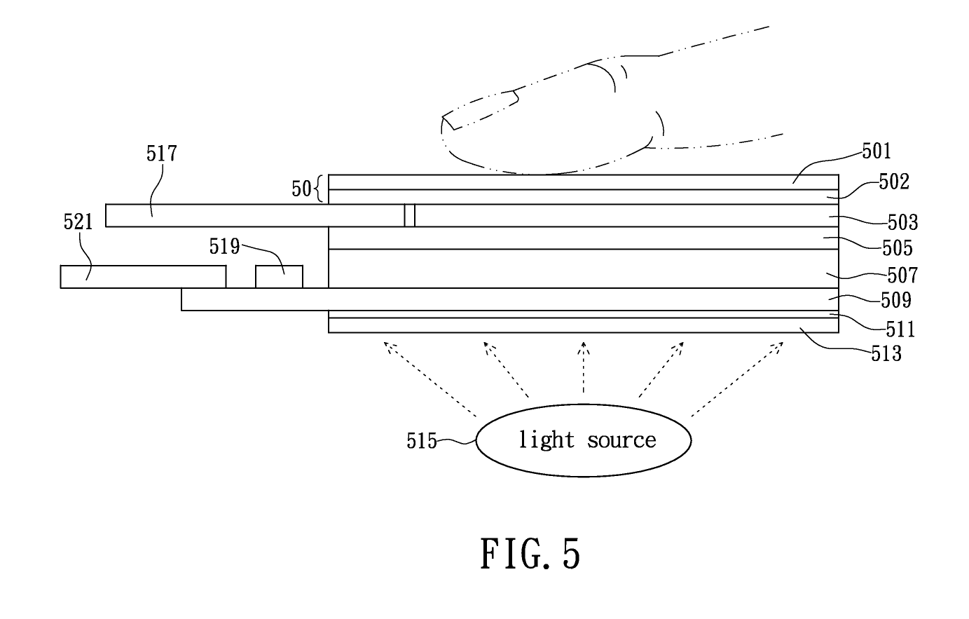

The fabrication of the claimed polarization device and a display module is schematically shown in FIG. 5.

A display module combined with the polarization device 50 with surface touch-controlled components is shown. The essential components of display module include, but not limited to, a liquid crystal layer 507 which is sandwiched by a top substrate 505 and a bottom substrate 509. The substrates 505, 509 are served to protect the liquid crystal layer 507.

The bottom substrate 509 is adhered with the bottom polarizer 513 with optical glue 511. Through the optical glue 503, the top substrate 505 is adhered to the polarization device 50 in accordance with the present invention. The polarization device 50 essentially includes a top polarizer 501 and a sensing electrode layer 502 within a touch-controlled panel.

A light source 515 is disposed below the display module. The display module is operatively driven by a driver chip 519 which is electrically connected with a display circuit board 521. The sensing electrode layer 502 is connected to a touch-controlled circuit board 517 for retrieving the touch-controlled signals for the use of a display circuit board 521 or the like.

In summation of the above description, disclosure is related to the method for manufacturing the polarizer with touch-sensitive elements. The method and the polarization device are exemplarily adapted to the polarizer (top polarizer or bottom polarizer) originally used in an LCD or an OLED display. The polarization device in accordance with the present invention is not only implementing a thin in-cell touch-controlled display, even thinner than a one-glass solution (OGS) display, but also reducing the space usage of the display. The method allows cost down as it provides a simplified solution.

The above-mentioned descriptions represent merely the exemplary embodiment of the present disclosure, without any intention to limit the scope of the present disclosure thereto. Various equivalent changes, alternations or modifications based on the claims of present disclosure are all consequently viewed as being embraced by the scope of the present disclosure.

What is claimed is:

1. A method for manufacturing touch-sensitive element on a polarizer, comprising:
preparing a substrate with function of light polarization;
coating a first transparent conductive material onto the substrate;
patterning the first transparent conductive material on the substrate, and forming a plurality of first electrodes, first electrode leads, second electrodes, second wires, and second electrode leads, and the first electrodes and the second electrodes form the electrodes on the substrate along different axial directions, wherein the adjacent first electrodes are not connected, and the adjacent second electrodes are connected via the second wire; the first electrode leads are separately connected to multiple paths with non-continuous first electrodes, and the second electrode leads are separately connected to multiple paths with continuous second electrodes;
inject-printing insulating material between the non-continuous first electrodes, and forming bridged insulating layers between the adjacent non-continuous first electrodes;
inject-printing second transparent conductive material on each bridged insulating layer between the adjacent first electrodes; and
curing the second transparent conductive material and the bridged insulating layer for forming the plurality of first wires between the adjacent first electrodes, wherein the first wire is electrically to bridge the two adjacent first electrodes, and the first wire is insulated from the second wire.

2. The method according to claim 1, wherein the substrate with function of light polarization is an optical polarizer disposed in an LCD or an organic light-emitting diode display.

3. The method according to claim 1, wherein the first transparent conductive material or the second transparent conductive material is the one selected from Indium Tin Oxide (ITO), nano silver, nano Cu, conductive polymer, carbon nanotube, Graphene, AgBr, and Indium Gallium Zinc Oxide (IGZO).

4. The method according to claim 1, wherein the step of curing is a UV curing or a thermo curing.

5. The method according to claim 1, wherein the step of patterning is a dry-etching procedure or a wet-etching procedure.

6. The method according to claim 5, wherein the dry-etching procedure is the one selected from coating etching pastes, laser engraving, and shutter-mask evaporation.

7. The method according to claim 5, wherein the wet-etching procedure is a photolithography procedure.

8. The method according to claim 1, wherein the step of coating is a dry coating process or a wet coating process.

9. The method according to claim 8, wherein the dry coating process is made by the one selected from sputtering, evaporation, and Chemical Vapor Deposition.

10. The method according to claim 8, wherein the wet coating process is the one selected from slot-die process, gravure, dipping, inject-printing, and spraying.

11. A polarization device made by the method for manufacturing touch-sensitive element on the polarizer according to claim 1, wherein the polarization device is adapted to a display module, comprising:
a substrate with function of light polarization;
a plurality of patterned first electrodes, first electrode leads, second electrodes, second wires, and second electrode leads formed on the substrate, wherein the first electrodes and the second electrodes are respectively formed as adjacent non-continuous and continuous electrodes; the second wire is electrically connected in between the adjacent second electrodes, the first electrode leads form the paths as separately connected with the non-continuous first electrodes, and the second electrode leads form the paths as separately connected with the continuous second electrodes;
bridged insulating layers in between the non-continuous first electrodes, formed by inject-printing insulating material;
first wires, on the bridged insulating layer and electrically connected in between the adjacent first electrodes, formed by inject-printing transparent conductive material;
wherein, a fabrication of the substrate, the first electrodes, the first wires, the first electrode leads, the second electrodes, the second wires, the second electrode leads and the bridged insulating layer forms the polarization device with surface touch-controlled components.
